(19) United States
(12) Patent Application Publication
(10) Pub. No.: US 2003/0017637 A1
(43) Pub. Date: Jan. 23, 2003

(54) Technique for the fabrication of high resolution led printheads

(76) Inventors: David I. Kennedy, Ottawa (CA); P. Gunnar Wareberg, Cumberland (CA); Stephen E. Wilson, Ottawa (CA); Richard Woodfield, Almonte (CA)

Correspondence Address: MARKS & CLERK, P.O. BOX 957, STATION B, OTTAWA, ON, K1P 5S7, CA

(21) Appl. No.: 09/907,671

(22) Filed: Jul. 19, 2001

(51) Int. Cl. H01L 21/00

(52) U.S. Cl. 438/46; 438/47

(57) ABSTRACT

A method of fabricating high resolution, light emitting devices for printheads and the like is disclosed. An epitaxial layer of an alloy compound such as GaAs:P is used as the host material. Typically, p-type material is diffused into n-type material to form planar and isolated p-n junctions that provide individual light emitting pixels. In the method of this invention the shape of each pixel and the gap between pixels is controlled by tailoring the dimensions of the aperture through which thermal diffusion takes place and by providing a layer of modulation material over the diffusion aperture. This combination results in the control of lateral diffusion parameters such that both the shape of the pixels and the gap between can be controlled.

### FIELD OF THE INVENTION

This invention relates to light emitting diode arrays and more particularly to methods of fabricating high density linear arrays.

### BACKGROUND

Light emitting diode arrays are used in a wide variety of applications ranging from visual displays to linear arrays for use in printheads and the like. LED printheads are used to expose light sensitive materials such as electro-photographic receptors, film, printing paper and plates. These printheads can be used in applications such as film annotation, desktop or web press printing, printed circuit board manufacture, printing of professional and amateur photographs, textile manufacture and graphic creations. Typical resolution of such printheads range from 300 dots per inch (DPI) to 600 DPI, and higher resolution can be employed up to 1200 DPI.

The manufacture of high resolution light emitting diode (LED) displays require the fabrication of small, light emitting junctions, with adequate fill factors. In this description a fill factor is the ratio of LED (or pixel width), to pixel pitch and the factor is an important contributor to electro-photographic print quality. Although the fill factor is important it is also important that the gap between pixels is sufficient to achieve electrical isolation of the adjacent devices which are typically planar diffused p-n junctions.

For linear arrays having resolution of 600 DPI the emitting pixel dimensions are typically in the 20 to 25 micron range with inter pixel gaps of approximately 7 to 10 microns. At higher resolutions the pixel size reduces. Several techniques can be used to create the LED pixel and the technique selected depends largely on the type of material used to manufacture the device. For example, in the gallium arsenide phosphide (GaAsP) family of compound semiconductors, the preferred and conventional technique of creating p-n junctions is to employ a process called planar processing. In this procedure p-n junctions are selectively created in a first conductivity type material, for example an n-type gallium arsenide phosphide layer which, has been grown epitaxially onto a gallium arsenide substrate. The junctions are created by selectively diffusing a dopant material of a second conductivity type, for example p-type, through windows in a diffusion mask deposited on the surface of the n-type epitaxial layer. The windows are formed in the diffusion mask using a photolithographic process which is well known in the no semiconductor art. Typically, the gallium arsenide phosphide layer is exposed to an atmosphere of the p-type dopant at an elevated temperature, and the p-type dopant thermally diffuses into the n-type material.

An alternative approach to creating selective p-n junctions involves the application and delineation of a solid state diffusion source which would include for example a spin on p-type dopant source or ion implantation of the p-type dopant. As in the previously described process, the pixel spacing and dimensions are defined photolithographically.

In certain other materials such as gallium phosphide (GaP), gallium aluminum arsenide (GaAlAs), gallium aluminum indium phosphide (GaAlInP) and indium gallium nitride (InGaN) the preferred technique is to grow the p-n junctions in situ as sheet layers. The junctions are subsequently isolated by selective removal of p-type material using known etching techniques. Again, photolithographic techniques are used to define the regions designated for removal. The resulting surface is not planar and the junction formation techniques is referred to as mesa processing. Frequently the p-type layers are relatively thick and, as a result, the side ways etching which occurs during selective removal of the p-type material can preclude achievement of a high resolution and large fill factors. Accordingly, the gallium arsenide phosphide family of compounds is more typically used in the preparation of high resolution LED displays.

### SUMMARY OF THE INVENTION

The present invention provides a method of fabricating high resolution linear arrays wherein the pixel dimensions and gaps between pixels is controlled through the use of a modulation material over the diffusion windows during the thermal diffusion process.

Therefore, in accordance with the present invention there is provided a method of fabricating light emitting devices for use in a high density linear array comprising: selecting a semi-conducting material of a first conductivity type; depositing a dielectric layer on said semi-conducting material; forming openings in a given pattern in said dielectric layer by a photolithographic process; depositing a layer of modulation material in the openings; and thermally diffusing material of a second conductivity type through the modulation material; wherein the modulation material controls the diffusion profile of the second conductivity type material into the first conductivity type material, including the lateral spread of the dopant and thereby the size and shape of the emitting p-n junction.

### BRIEF DESCRIPTION OF THE DRAWINGS

The invention will now be described in greater detail with reference to the attached drawings wherein:

FIG. 1 is a cross sectional view of a gallium arsenide phosphide wafer in the diffusion process;

FIG. 2 is a cross sectional view of the wafer of FIG. 1 with the modulation material removed and a delineated metal contact on the p-type material; and

FIG. 3 is a top view of the device of FIG. 2.

### DETAILED DESCRIPTION OF THE INVENTION

For the sake of the following description the semiconductor material will be identified as gallium arsenide phosphide epitaxially grown on a gallium arsenide substrate. The gallium arsenide phosphide material is typically n-type and the diffusion involves the introduction of p-type impurity such as zinc into the n-type material. It is to be understood, however, that the description is directed to a preferred embodiment and is not intended to limit the process of the invention to these particular materials.

The fabrication of high resolution linear LED arrays according to the present invention is achieved by the controlled lateral diffusion of the dopant use to selectively create the p-n junctions. The aperture window through which the dopant is introduced into the semiconductor is designed to be smaller than the dimensions of the desired emitting pixel. The final dimensions of the emitting pixel, as well as the distance between pixel edges is achieved by controlled lateral diffusion of the dopant. This is achieved by a combination of the size and shape of the delineated diffusion aperture; the thickness and composition of the masking material used to delineate the diffusion aperture; and the dopant diffusion conditions including the thickness and composition of a modulation material deposited over the diffusion apertures.

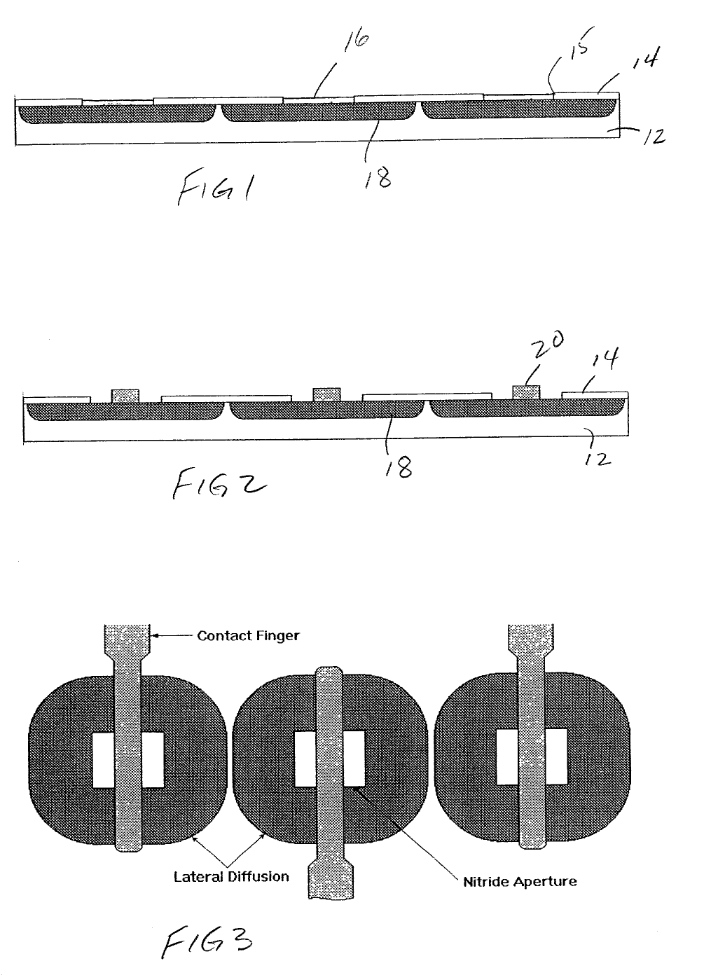

FIG. 1 is an example of the diffusion profile of isolated LED devices fabricated in accordance with the process of the present invention. As shown in FIG. 1 a layer 12 of n-type gallium arsenide phosphide is covered with a diffusion mask material 14 which is typically silicon nitride. The silicon nitride 14 is photolithographically processed to generate diffusion windows 15. The size and shape of the diffusion windows are carefully selected depending on the intended configuration of the LED array. In a preferred embodiment of the invention a layer of modulation material 16 is used to back fill the windows in the diffusion mask. Typically, the modulation material is silicon oxide deposited by a chemical vapor deposition, although other modulating materials can be used.

The thus processed wafer is then subject to a thermal diffusion process in an open tube diffusion process, although it is to be understood that other diffusion processes may be employed. Through the diffusion process the p-type material diffuses into the n-type layer and laterally under the dielectric diffusion mask. The extent of the lateral diffusion is carefully controlled by the process according to the present invention.

The thickness of the modulation material influences the surface concentration and the concentration gradient of the p-type dopant. It has been observed that the surface concentration is in the range of 10¹⁹ per cubic centimeter with a junction depth of approximately 4 microns. The modulation layer also prevents decomposition of the n-type layer during the diffusion cycle. Typically, the thickness of the modulation material for processes involving gallium arsenide phosphide is 40 nm.

The p-type dopant, typically zinc, goes through the oxide from a surrounding vapor but in a “modulated” fashion which effects both the p-dopant profile and the surface concentrations.

It is also within the scope of the present invention to use a spin on type p-doped silica material in which the p-type dopant is combined with the silica. The spin on material is typically applied to the wafer following etching of the diffusion windows.

The significance of the invention resides in the controlled lateral diffusion and narrow inter-pixel spacings along or near the surface of the semiconductor which creates the enlarged junction. The modulating oxide influences this as well as the vertical depth profile and surface concentration as mentioned above.

FIG. 2 shows the array of FIG. 1 following further processing in order to create p-type contacts 20 which are typically aluminum. It will be apparent to one skilled in the art that the array will also have n-type contacts for making electrical connection to the n-type material 12—either the GaAsP epitaxial layer or the GaAs substrate.

FIG. 3 is a top view of the linear array of FIG. 2. FIG. 3 is particularly relevant in showing the extent of the lateral diffusion around the masking window. As shown in FIG. 3 the created pixel is substantially circular with a well defined inter pixel gap.

Although a particular embodiment of the present invention has been described and illustrated it will be apparent to one skilled in the art that variations to the basic concept. It is to be understood, however, that such variations will fall within the true scope of the invention as defined by the appended claims.

We claim:

1. A method of fabricating light emitting devices for use in a high density linear array comprising:
selecting a semi-conducting material of a first conductivity type;
depositing a dielectric layer on said semi-conducting material;
forming openings in a given pattern in said dielectric layer by a photolithographic process;
depositing a layer of modulation material in said openings; and
thermally diffusing material of a second conductivity type through said modulation material;
wherein said modulation material controls the diffusion profile of the second conductivity type material into the first conductivity type material.

2. The method as defined in claim 1 wherein the step of thermally diffusing said material of a second conductivity type employs an open tube diffusion process.

3. The method as defined in claim 1 wherein said second conductivity type material is incorporated into said modulation material.

4. The method as defined in claim 1 wherein said semi-conducting material is GaAsP.

5. The method of claim 4 wherein said first conductivity type material is N-type material and said second conductivity type material is P-type.

6. The method as defined in claim 4 wherein said P-type material is Zinc.

7. The method as defined-in claim 1 wherein said dielectric layer is Si₃N₄.

8. The method as defined in claim 7 wherein said modulation material is SiO.

9. The method as defined in claim 1 wherein contact material is provided to respective conductivity types for use in powering said light emitting devices.
